(19) United States
(12) Patent Application Publication
(10) Pub. No.: US 2005/0248041 A1
(43) Pub. Date: Nov. 10, 2005

(54) Electronic device with high lead density

(75) Inventors: Teng Hock Kuah, Singapore (SG); Zhi Pan Zhang, Singapore (SG); Shuai Ge Lee, Singapore (SG); Chun Yu Li, Singapore (SG); Yi Lin, Singapore (SG)

Correspondence Address: OSTROLENK FABER GERB & SOFFEN, 1180 AVENUE OF THE AMERICAS, NEW YORK, NY, 100368403, US

(73) Assignee: ATM Technology Singapore Pte Ltd, Singapore (SG)

(21) Appl. No.: 10/839,956

(22) Filed: May 5, 2004

(51) Int. Cl. H01L 23/495

(52) U.S. Cl. 257/787

(57) ABSTRACT

An electronic device moldable to form a leadless electronic package and a method of forming the electronic device are provided. The electronic device comprises a die pad adapted for attachment of a die and a frame surrounding the die pad. A plurality of leads extend from the frame towards the die pad such that each lead has a bonding site on a top surface thereof configured for attachment of a bonding wire. The said leads include a first set of leads having bonding sites located substantially on a first plane and a second set of leads having bonding sites located substantially on a second plane that is parallel to but spaced from the first plane.

### FIELD OF THE INVENTION

The invention relates to an electronic device with leads, such as a leadframe of a Quad Flat No-Lead (“QFN”)-type package, and to a method of manufacturing such an electronic device.

### BACKGROUND AND PRIOR ART

QFN packages are known for their small size, cost-effectiveness and good production yields. They are performance and efficiency competitive with array packages including fine pitch ball grid array packages because they do not require ball grid array substrates, or expensive ball tooling. QFN packages also possess certain mechanical advantages for high-speed circuits including improved co-planarity and heat dissipation. Since QFN packages do not have gull wings leads which at times can act as antennas, creating “noise” in high-frequency applications, their electrical performance is superior to traditional leaded packages.

QFN packages are best used in low-lead count arrays. Nevertheless, another benefit of QFN packages, when compared to standard leadframe packages, is their ability to offer higher density interconnects. The leads of a QFN package can be placed in single-, dual- or triple-wiring rows to enable increased functionality in a single package, which translates into lower costs. QFN packages also take advantage of the fact that leadframe-based packaging is lower in cost than laminate-based substrates because it is less expensive to simply etch a thin piece of copper to form the leadframe than to fabricate a printed circuit board through many costly manufacturing steps.

A major advantage of QFN packages over traditional standard leadframe packages is its small footprint as the width of the package is not significantly larger than the width of its encapsulated semiconductor integrated circuit or die. Typically, wire connections are made between leads on a leadframe carrier and electrical contacts on the integrated circuit or die. The leads have to be spaced apart and insulated so as to form separate electrical connections to an external surface of a package.

In order to reduce a size of a package while maintaining the number of electrical connections, it is important to make better use of a real estate offered by the leadframe by having multiple wiring rows or leads manufactured on the leadframe. In order to increase lead density, prior art methods of fabricating a leadframe have focused on adding more layers of materials on leadframes, or to make leadframes with very fine lead widths. An example of a prior art method of fabricating several layers of materials on a leadframe is disclosed in U.S. Pat. No. 6,087,204 for “Method of Making a Multi-Layer Lead Frame”.

An example of a prior art method of fabricating a leadframe with high-density electrical leads is disclosed in U.S. patent Publication No. 2003/0111717A1 entitled “Semiconductor Device and Method of Manufacturing the Same”. This publication discloses promoting the increase of the number of pins in a QFN package by having a plurality of leads made of the same metal as the die pad, and having die pad supports arranged around the die pad so as to surround the die pad. The lead tips on one side are extended to positions close to the die pad so that the intervals between adjoining leads on a side nearer the die pad are smaller than those on a side nearer a side surface of the package.

This method requires the production of leads with very fine widths by etching. Since the elongated leads are thin and fragile, they are more prone to damage or deformation. Moreover, as the leads are formed next to one another on a single plane, one has to satisfy the competing demands of providing a sufficient surface area to connect a bonding wire to it but to provide sufficient space between the leads to prevent inadvertent contact between adjacent leads or bonding wires. Thus, the ability to reliably reduce the internal pitch between adjacent leads is limited.

### SUMMARY OF THE INVENTION

It is an object of the invention to seek to provide an improved leadframe that better utilizes an internal area of a package to locate its leads, so as to achieve a higher lead density. Thus, it also seeks to facilitate increasing the number of leads locatable on the leadframe for a given package size.

According to a first aspect of the invention, there is provided an electronic device moldable to form a leadless electronic package, comprising: a die pad adapted for attachment of a die; a frame surrounding the die pad; a plurality of leads extending from the frame towards the die pad, each lead having a bonding site on a top surface thereof configured for attachment of a bonding wire; wherein the leads include a first set of leads having bonding sites located substantially on a first plane; and a second set of leads having bonding sites located substantially on a second plane that is parallel to but spaced from the first plane.

According to a second aspect of the invention, there is provided a method of forming an electronic device that is moldable to form a leadless electronic package, comprising the steps of: fully etching the electronic device to form a die pad adapted for attachment of a die and a frame surrounding the die pad; and partially etching the electronic device from opposite planar surfaces of the electronic device to form a plurality of leads extending from the frame towards the die pad, each lead having a bonding site on a top surface thereof configured for attachment of a bonding wire; wherein the leads include a first set of leads having bonding sites located substantially on a first plane; and a second set of leads having bonding sites located substantially on a second plane that is parallel to but spaced from the first plane.

It would be convenient hereinafter to describe the invention in greater detail by reference to the accompanying drawings which illustrate one embodiment of the invention. The particularity of the drawings and the related description is not to be understood as superseding the generality of the broad identification of the invention as defined by the claims.

### BRIEF DESCRIPTION OF THE DRAWINGS

Examples of an electronic device and method of fabricating the same in accordance with the invention will now be described with reference to the accompanying drawings, in which:

FIG. 1 illustrates plan views of a molded QFN semiconductor package (a) after molding, and (b) after singulation respectively;

FIG. 2 illustrates an isometric view of the molded package after singulation;

FIG. 3 illustrates an isometric view of a top or die-attach side of a leadframe carrier according to the preferred embodiment of the invention that is suitable for use in forming the package of FIG. 1;

FIG. 4 illustrates an isometric view of a bottom or tape side of leadframe carrier, which is opposite its die-attach side that is shown in FIG. 3; and

FIG. 5 illustrates a plan view of a corner of the leadframe carrier on its bottom or tape side;

FIGS. 6(a) and 6(b) illustrate cross-sectional views of the inner leads and outer leads of the leadframe carrier respectively, looking from sections A-A and B-B of FIG. 5 respectively;

FIG. 7 illustrates plan views of (a) a die-attach side, and (b) a tape side opposite the die-attach side of the leadframe carrier, showing etching regions for manufacturing a leadframe carrier according to the preferred embodiment of the invention; and

FIG. 8 illustrates an isometric view of a molded QFN semiconductor package, including its contents.

### DETAILED DESCRIPTION OF THE PREFERRED EMBODIMENT

FIG. 1(a) illustrates a plan view of a molded leadless QFN semiconductor package 10 after molding. The view shows a bottom side of the leadless package with exposed electrical contacts. It shows a base of a die pad 12 to which an integrated circuit die has been attached to a top side, areas covered by a molding compound 14, outer leads 16 and inner leads 18.

FIG. 1(b) illustrates a plan view of the leadless molded package 11 after singulation. An outer peripheral of the package 11 has been diced adjacent to the position of the outer leads 16 so as to leave a sufficient surface area remaining of the outer leads 16 and inner leads 18 for contact with a mounting surface.

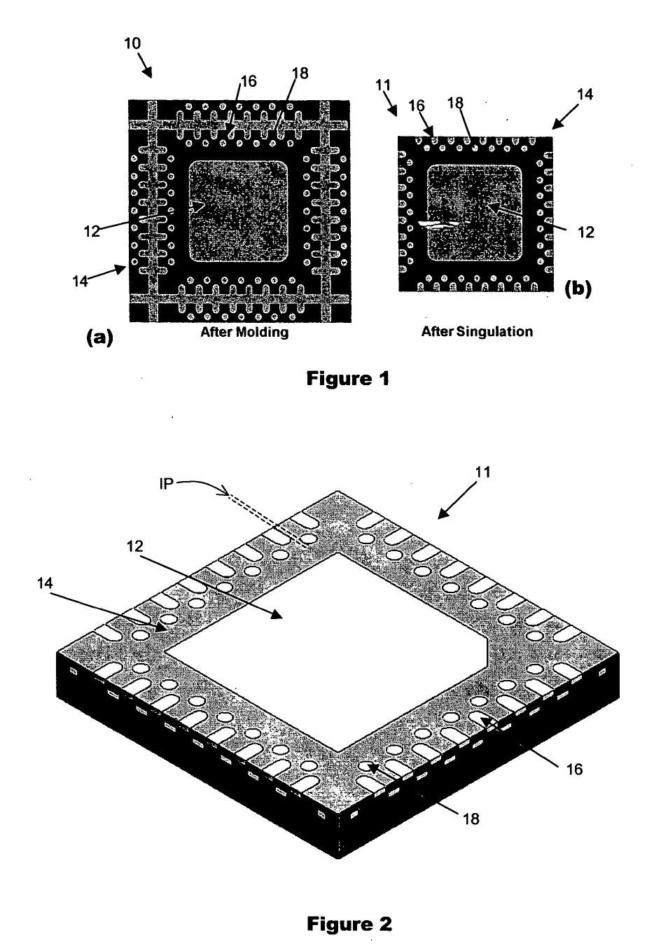

FIG. 2 illustrates an isometric view of the molded package after singulation. An internal pitch (“IP”) of leads of the QFN package 11 is shown, which refers to a distance between adjacent contact leads to which bonding wires may be connected. In the preferred embodiment of the invention, the leads comprising exposed outer leads 16 and inner leads 18 are staggered both horizontally and vertically in their arrangement on the bottom side of the package so that the actual distance between bonding points may be larger than the internal pitch. A smaller internal pitch between leads may thus be achieved by this staggered arrangement.

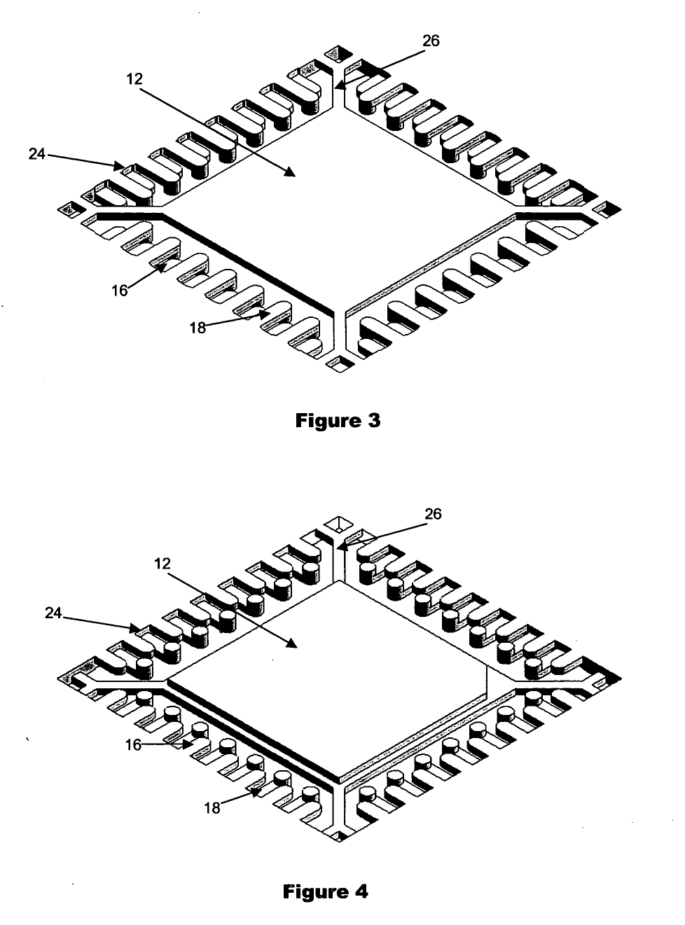

FIG. 3 illustrates an isometric view of a top or die-attach side of an electronic device in the form of a leadframe carrier according to the preferred embodiment of the invention that is suitable for use in forming the package of FIG. 1. FIG. 4 illustrates an isometric view of a bottom or tape side of leadframe carrier, which is opposite its die-attach side that is shown in FIG. 3. In use, a typical strip of leadframe may comprise a matrix array consisting of a plurality of said leadframe carriers 24. The leadframe 24 has a die pad 12 which is adapted for attachment of an integrated circuit die and a frame surrounding the die pad 12. It also has a first set of leads or inner leads 18, and a second set of leads or outer leads 16, extending from the frame towards the die pad 12 for making electrical connections from electrical contacts on the die 20 to the leads 16, 18. Tie bars 26 are shown which hold the die pad 12 to the leadframe 24. The inner leads 18 are formed longer than the outer leads 16.

The top surface represented is the die-attach side of the leadframe 24 on which a die is mountable onto the leadframe 24, while the tape side is at the bottom surface where an adhesive tape is attached during molding in order to expose certain portions of the leads 16, 18 after the molding process. The leads 16, 18 each have bonding sites on the top surface thereof configured for attachment of a bonding wire.

When viewed from the top surface, it can be seen that positions of the leadframe 24 corresponding to the positions of the outer leads 16 are set at a lower level relative to the inner leads 18. Correspondingly, the first set of leads or inner leads 18 have bonding sites located substantially on a first plane and the second set of leads or outer leads 16 have bonding sites located substantially on a second plane that is parallel to but spaced from the first plane 18. The production of outer leads 16 at different heights as compared to the inner leads 18 can be achieved by half-etching, as described in more detail below.

Comparatively, when viewed from the bottom side, a substantial portion of the bottom surfaces of the inner leads 18 are at lower heights than the bottom surfaces of the outer leads 16. Accordingly, a substantial part of the bottom surfaces of the inner leads 18 lies on a third plane, and a substantial part of the bottom surfaces of the outer leads 16 lies on a fourth plane that is parallel to but spaced from the third plane. This is also achievable by selectively half-etching the leadframe 24.

Selective half-etching from each side of the leadframe 24 serves to physically separate the contact parts of the outer leads 16 and inner leads 18 from each other. The embodiment thus forms physically-separate outer leads 16 and inner leads 18 in a stepped arrangement using the selective half-etching method from dual sides of the leadframe 24 as described below. An outer lead 16 is interspersed between adjacent inner leads 18 and vice versa so as to also achieve a staggered arrangement of bonding sites.

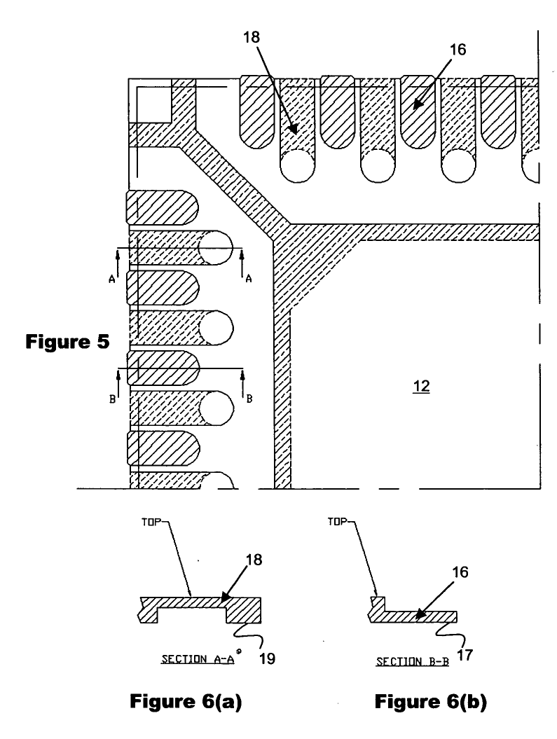

FIG. 5 illustrates a plan view of a corner of the leadframe carrier 24 on its bottom or tape side. The outer leads 16 have different lengths as compared to the inner leads 18 and terminate at different distances from the die pad 12. Hence, the outer leads 16 and inner leads 18 can have clearly differentiated contact points or pads, and bonding points on the leads can be separated by a greater distance than the internal pitch of the leadframe 24.

FIGS. 6(a) and 6(b) illustrate cross-sectional views of the inner leads 18 and outer leads 16 of the leadframe carrier 24 respectively, looking from sections A-A and B-B of FIG. 5 respectively. A bottom surface of each lead 16, 18 that is opposite to its top surface is configured to be at least partially exposed in a molded electronic package. The inner lead 18 has a circular exposed surface 19 after molding, whereas the outer lead 16 has an elongated exposed surface 17 in a traditional form after molding. The surface area of the exposed surface 19 of the inner lead 18 is of relatively smaller size as compared to the exposed surface 17 of the outer lead 16. The exposed surfaces 17, 19 are coplanar so that they are relatively flush with a surface of the package 10 after molding. An arrangement of the respective exposed surfaces 17, 19 in a molded package can be seen in FIG. 1.

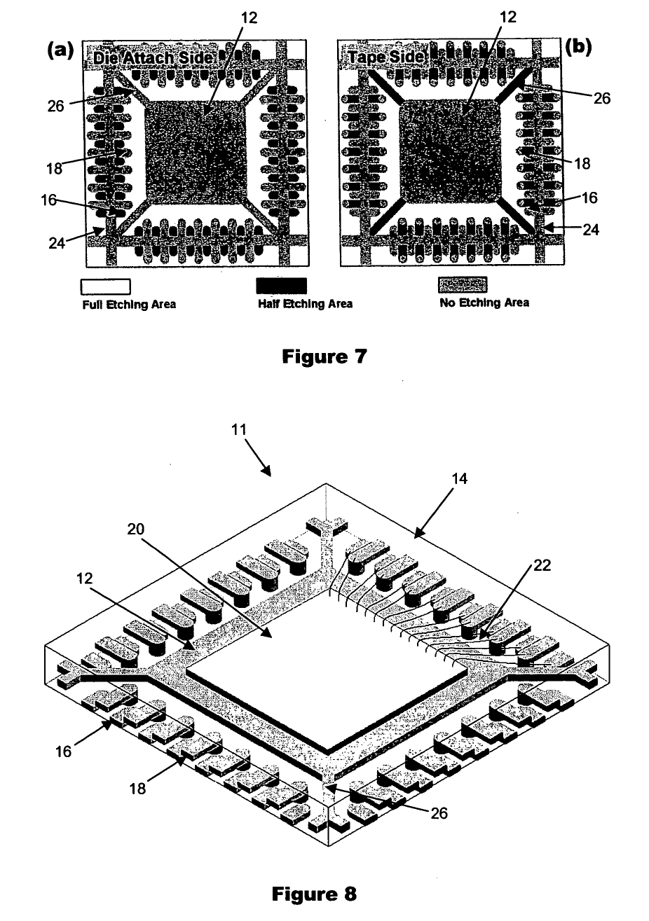

FIG. 7 illustrates a plan view of a die-attach side of the leadframe carrier 24, showing etching regions for manufacturing a leadframe carrier 24 according to the preferred embodiment of the invention. The said leadframe 24 is produced by etching from opposite coplanar surfaces from a single piece of material, such as copper, on both sides thereof. The regions where full etching is performed are represented as unshaded in the illustration. Full etching refers to etching completely through the leadframe 24 to leave through-holes in those regions. The regions where half-etching is conducted are represented in dark shading. Half-etching means that the leadframe is not etched completely at these regions. Instead, etching is performed only half-way through the leadframe material, leaving half the material on the leadframe 24. The regions where no etching is conducted are represented with light shading.

FIG. 7(b) illustrates a plan view of the tape side of the leadframe 24 opposite the die-attach side illustrated in FIG. 7(a). It shows the etching performed on this tape side of the leadframe 24 as compared to the die-attach side illustrated in FIG. 7(a). Essentially, the half-etching areas on the tape side are different from those on the die-attach side and positioned such as to produce stepped outer leads 16 and inner leads 17. By selectively half-etching the different regions of the leadframe 24 as indicated in FIGS. 7(a) and 7(b), a leadframe according to the preferred embodiment of the invention can be formed. The etching process may comprise a traditional etching method, except that etching is performed from both sides of the leadframe.

Full etching can be performed to form the die pad 12 and the frame surrounding the die pad 12. The plurality of outer leads 16 and inner leads 18 can be formed by said partial or half-etching selectively from opposite planar surfaces of the leadframe 24. In particular, the top surfaces of the inner leads 18 and die pad 12 are not etched and are coplanar. The bottom surfaces of the outer leads 16 and die pad 12 are not etched and are also coplanar. The top surfaces of the outer leads 16 are formed by partially etching a top surface of the leadframe 24 such that the bonding sites of the inner leads 18 are higher as compared to the bonding sites of the outer leads 16. Correspondingly, a substantial part of the bottom surfaces of the inner leads 18 are formed by partially etching a bottom surface of the leadframe 24 such that these surfaces are higher are compared to the bottom surfaces of the outer leads 16, but leaving circular exposed portions 19 that is unetched and therefore coplanar with the bottom surfaces of the outer leads 16.

FIG. 8 illustrates an isometric view of a molded QFN semiconductor package 11, including its contents. An integrated circuit die 20 is attached onto the die pad 12. Surrounding the die pad 12 are the leads comprising outer leads 16 and inner leads 18. Electrical connections are made with bonding wires 22 between electrical contacts on the die 20 and the respective outer leads 16 and inner leads 18. While making connections between electrical contacts on the die 20 to each lead position, adjacent bonding wires 22 are bonded respectively to an outer lead 16 and an inner lead 18. The internal pitch of the leads can be reduced as compared to conventional leadframe designs without sacrificing reliability, since the distance between bonding positions on the leads 16, 18 can be greater than the conventional internal pitch of the leadframe 24.

After the bonding wires 22 are bonded to form the electrical connections, the package 11 is molded with a molding compound 14 to protect the contents of the package 11. Before molding, and usually before a die is attached onto the leadframe 24, an adhesive tape (not shown) can be attached to a bottom surface of the leadframe 24 to ensure that molding compound 14 only encapsulates one side of the leadframe 24 during molding. The other side of the leadframe 24 is not molded so as to expose the base of the die pad 12, and exposed contact surfaces 17, 19 on the outer leads 16 and inner leads 18, as shown in FIGS. 1(a) and 1(b). That bottom side of the die pad 12, and exposed parts of the outer leads 16 and inner leads 18 can be exposed for electrical coupling to a mounting surface.

While the above description relates to the formation of a typical QFN package, it should be understood that the principles of the invention are applicable to produce leadframes having smaller internal pitches for other forms of leadframe packages.

It would be appreciated that the embodiment of the invention provides a relatively simpler and cost-effective way of increasing the lead density of a semiconductor package using an internal area of a package to locate leads, such as a QFN package. It optimizes the productive use of the internal areas of the package that might otherwise be wasted. As a result, a smaller package size or increased pin count can be achieved as compared to conventional methods by increasing lead density.

Another advantage of the method according to the preferred embodiment of the invention is that the package can be manufactured using existing package assembly and leadframe infrastructure for producing conventional QFN packages. Therefore, it does not incur significant additional costs in order to take advantage of the benefits that the invention provides. Full and half-etching is already practised for the manufacture of leadframes (see for example, U.S. patent publication No. US2003/0111717A1 mentioned above). Furthermore, to avoid increasing costs unnecessarily, existing methods of die bonding, wire bonding, molding and singulation can be performed on the etched leadframe fabricated according to the preferred embodiment of the invention.

The invention described herein is susceptible to variations, modifications and/or additions other than those specifically described and it is to be understood that the invention includes all such variations, modifications and/or additions which fall within the spirit and scope of the above description.

1. Electronic device moldable to form a leadless electronic package, comprising:
a die pad adapted for attachment of a die;
a frame surrounding the die pad;
a plurality of leads extending from the frame towards the die pad, each lead having a bonding site on a top surface thereof configured for attachment of a bonding wire;
wherein the leads include a first set of leads having bonding sites located substantially on a first plane; and
a second set of leads having bonding sites located substantially on a second plane that is parallel to but spaced from the first plane.

2. Electronic device as claimed in claim 1, wherein a bottom surface of each lead that is opposite to its top surface is configured to be at least partially exposed in the molded electronic package.

3. Electronic device as claimed in claim 2, wherein the said exposed bottom surfaces of the first and second sets of leads are coplanar.

4. Electronic device as claimed in claim 3, wherein the said exposed bottom surfaces have surface areas that are of substantially different sizes.

5. Electronic device as claimed in claim 1, wherein a lead of the first set of leads is interspersed between adjacent leads of the second set of leads.

6. Electronic device as claimed in claim 5, including bonding wires connecting the die to each bonding site such that adjacent bonding wires are connected respectively to a lead of the first set of leads and a lead of the second set of leads.

7. Electronic device as claimed in claim 1, wherein a substantial part of a surface of the first set of leads opposite the top surface of the first set of leads lies on a third plane, and a substantial part of a surface of the second set of leads opposite the top surface of the second set of leads lie on a fourth plane that is parallel to but spaced from the third plane.

8. Electronic device as claimed in claim 7, wherein the fourth plane is coplanar with a bottom surface of the die pad that is opposite to its die-attachment surface.

9. Electronic device as claimed in claim 1, wherein the first set of leads are longer than the second set of leads.

10. Electronic device as claimed in claim 1, wherein the second set of leads are formed by partially etching a top surface of the electronic device such that the bonding sites of the second set of leads are of a different height as compared to the bonding sites of the first set of leads.

11. Electronic device as claimed in claim 1, wherein the electronic device is formed from etching a single piece of material.

12. Method of forming an electronic device that is moldable to form a leadless electronic package, comprising the steps of:
fully etching the electronic device to form a die pad adapted for attachment of a die and a frame surrounding the die pad; and
partially etching the electronic device from opposite planar surfaces of the electronic device to form a plurality of leads extending from the frame towards the die pad, each lead having a bonding site on a top surface thereof configured for attachment of a bonding wire;
wherein the leads include a first set of leads having bonding sites located substantially on a first plane; and
a second set of leads having bonding sites located substantially on a second plane that is parallel to but spaced from the first plane.

13. Method as claimed in claim 12, wherein at least a part of a bottom surface of each lead that is opposite to its top surface is not etched so as to expose such part in the molded electronic package.

14. Method as claimed in claim 12, including forming the first set of leads to be longer than the second set of leads by etching.

15. Method as claimed in claim 12, including locating a lead of the first set of leads to be between adjacent leads of the second set of leads by etching.

16. Method as claimed in claim 12, wherein the step of forming the second set of leads includes partially etching from a top surface of the electronic device such that the bonding sites of the second set of leads are of a different height as compared to the bonding sites of the first set of leads.

17. Method as claimed in claim 12, wherein a substantial part of a bottom surface of the first set of leads opposite the top surface of the first set of leads lies on a third plane, and a substantial part of a bottom surface of the second set of leads opposite the top surface of the second set of leads lie on a fourth plane that is parallel to but spaced from the third plane.

18. Method as claimed in claim 17, wherein the bottom surfaces of the leads on the fourth plane and a bottom surface of the die pad that is opposite to its die-attachment surface are not etched.

19. Method as claimed in claim 12, wherein the top surfaces of the leads on the first plane and an attachment surface of the die pad are not etched.

20. Method as claimed in claim 12, including etching a single piece of material to form the electronic device.
